(19) United States
(12) Patent Application Publication
(10) Pub. No.: US 2025/0255029 A1
(43) Pub. Date: Aug. 7, 2025

(54) IMAGE SENSING DEVICE

(71) Applicant: SK hynix Inc., Icheon-si (KR)

(72) Inventors: Sung Ho CHOI, Icheon-si (KR); Hee Dong KIM, Icheon-si (KR); Hyun Soo LIM, Icheon-si (KR); Hyeon Jeong LEE, Icheon-si (KR)

(21) Appl. No.: 19/043,050

(22) Filed: Jan. 31, 2025

(30) Foreign Application Priority Data
Feb. 1, 2024 (KR) 10-2024-0016191

(51) Int. Cl. H10F 39/00; H04N 25/766

(52) U.S. Cl. CPC H10F 39/811; H04N 25/766; H10F 39/8023; H10F 39/8037; H10F 39/8053; H10F 39/8063

(57) ABSTRACT

An image sensing device includes a first pixel group including first unit pixels arranged in a row direction and a column direction; a second pixel group including second unit pixels arranged in the row direction and the column direction; a first transfer control signal line connected to any one of the first unit pixels located in a first direction with respect to a center of the first pixel group, and connected to any one of the second unit pixels located in a second direction perpendicular to the first direction with respect to a center of the second pixel group; and a second transfer control signal line connected to a remaining one of the first unit pixels located in the first direction, and connected to a remaining one of the second unit pixels located in the second direction.

### PRIORITY CLAIM AND CROSS-REFERENCE TO RELATED APPLICATION

This patent document claims the priority and benefits of Korean patent application No. 10-2024-0016191, filed on Feb. 1, 2024, the disclosure of which is incorporated herein by reference in its entirety as part of the disclosure of this patent document.

### TECHNICAL FIELD

The technology and implementations disclosed in this patent document generally relate to an image sensing device.

### BACKGROUND

An image sensing device is a device for capturing optical images by converting light into electrical signals using a photosensitive semiconductor material which reacts to light. With the development of automotive, medical, computer and communication industries, the demand for high-performance image sensing devices is increasing in various fields such as smart phones, digital cameras, game machines, IoT (Internet of Things), robots, security cameras and medical micro cameras.

The image sensing device may be roughly divided into CCD (Charge Coupled Device) image sensing devices and CMOS (Complementary Metal Oxide Semiconductor) image sensing devices. The CCD image sensing devices offer a better image quality, but they tend to consume more power and are larger as compared to the CMOS image sensing devices. The CMOS image sensing devices are smaller in size and consume less power than the CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the disclosed technology relate to an image sensing device capable of generating image data and phase data.

Various embodiments of the disclosed technology relate to an image sensing device capable of generating phase data without outputting additional pixel signals using pixel signals generated by a plurality of unit pixels included in a pixel array.

In accordance with an embodiment of the disclosed technology, an image sensing device may include: a first pixel group formed to include a plurality of first unit pixels arranged in a row direction and a column direction, the first unit pixels configured to respond to incident light and generate first pixel signals, respectively; a second pixel group disposed adjacent to the first pixel group in the row direction and including a plurality of second unit pixels arranged in the row direction and the column direction, the second unit pixels configured to respond to the incident light and generate second pixel signals, respectively; a first transfer control signal line connected to any one of the first unit pixels located in a first direction with respect to a center of the first pixel group, and connected to any one of the second unit pixels located in a second direction perpendicular to the first direction with respect to a center of the second pixel group; and a second transfer control signal line connected to a remaining one of the first unit pixels located in the first direction, and connected to a remaining one of the second unit pixels located in the second direction.

In some implementations, the image sensing device may further include: a third transfer control signal line connected to any one of the first unit pixels located in a third direction opposite to the first direction, and connected to any one of the second unit pixels located in a fourth direction opposite to the second direction; and a fourth transfer control signal line connected to a remaining one of the first unit pixels located in the third direction, and connected to a remaining one of the second unit pixels located in the fourth direction.

In some implementations, the image sensing device may further include: a third pixel group disposed adjacent to the first pixel group in the column direction and including a plurality of third unit pixels, the third unit pixels configured to respond to incident light and generate third pixel signals, respectively; a fourth pixel group disposed adjacent to the third pixel group in the row direction and including a plurality of fourth unit pixels, the fourth unit pixels configured to respond to incident light and generate fourth pixel signals, respectively; and a fifth transfer control signal line, a sixth transfer control signal line, a seventh transfer control signal line, and an eighth transfer control signal line that are connected to the third unit pixels and the fourth unit pixels.

In some implementations, the image sensing device may further include: a processor configured to calculate image data based on pixel signals that are output from the first pixel group, the second pixel group, the third pixel group, and the fourth pixel group, in response to transfer control signals having an activation voltage level, the transfer control signals provided through the first transfer control signal line, the second transfer control signal line, the third transfer control signal line, the fourth transfer control signal line, the fifth transfer control signal line, the sixth transfer control signal line, the seventh transfer control signal line, and the eighth transfer control signal line.

In some implementations, the fifth transfer control signal line is connected to any one of the third unit pixels located in the first direction with respect to the center of the third pixel group, and is connected to any one of the fourth unit pixels located in the second direction with respect to the center of the fourth pixel group; and the sixth transfer control signal line is connected to a remaining one of the third unit pixels located in the first direction and is connected to a remaining one of the fourth unit pixels located in the second direction.

In some implementations, the image sensing device may further include: a processor configured to calculate phase data based on pixel signals that are output from the first pixel group, the second pixel group, the third pixel group, and the fourth pixel group, in response to transfer control signals having an activation voltage level, the transfer control signals provided through the first transfer control signal line, the second transfer control signal line, the seventh transfer control signal line, and the eighth transfer control signal line.

In some implementations the fifth transfer control signal line is connected to any one of the third unit pixels located in the second direction with respect to the center of the third pixel group, and is connected to any one of the fourth unit pixels located in the first direction with respect to the center of the fourth pixel group; and the sixth transfer control signal line is connected to a remaining one of the third unit pixels located in the second direction, and is connected to a remaining one of the fourth unit pixels located in the first direction.

In some implementations, the image sensing device may further include: a processor configured to calculate phase data based on pixel signals that are output from the first pixel group, the second pixel group, the third pixel group, and the fourth pixel group, in response to transfer control signals having an activation voltage level, the transfer control signals provided through the first transfer control signal line, the second transfer control signal line, the seventh transfer control signal line, and the eighth transfer control signal line.

In some implementations, the fifth transfer control signal line is connected to any one of the third unit pixels located in the third direction with respect to the center of the third pixel group, and is connected to any one of the fourth unit pixels located in the fourth direction with respect to the center of the fourth pixel group; and the sixth transfer control signal line is connected to a remaining one of the third unit pixels located in the third direction and is connected to a remaining one of the fourth unit pixels located in the fourth direction.

In some implementations, the image sensing device may further include: a processor configured to calculate phase data based on pixel signals that are output from the first pixel group, the second pixel group, the third pixel group, and the fourth pixel group, in response to transfer control signals having an activation voltage level, the transfer control signals provided through the first transfer control signal line, the second transfer control signal line, the fifth transfer control signal line, and the sixth transfer control signal line.

In some implementations, the fifth transfer control signal line is connected to any one of the third unit pixels located in the fourth direction with respect to the center of the third pixel group, and is connected to any one of the fourth unit pixels located in the third direction with respect to the center of the fourth pixel group; and the sixth transfer control signal line is connected to a remaining one of the third unit pixels located in the fourth direction and is connected to a remaining one of the fourth unit pixels located in the third direction.

In some implementations, the image sensing device may further include: a processor configured to calculate phase data based on pixel signals that are output from the first pixel group, the second pixel group, the third pixel group, and the fourth pixel group, in response to transfer control signals having an activation voltage level, the transfer control signals provided through the first transfer control signal line, the second transfer control signal line, the fifth transfer control signal line, and the sixth transfer control signal line.

In some implementations, the image sensing device may further include a row driver configured to provide a transfer control signal having an activation voltage level or a deactivation voltage level through each transfer control signal line.

In some implementations, the image sensing device may further include: a first microlens disposed to overlap the first pixel group; and a second microlens disposed to overlap the second pixel group.

In some implementations, each of the first unit pixels includes a first optical filter; and each of the second unit pixels includes a second optical filter.

In some implementations, the image sensing device may further include: a third pixel group disposed adjacent to the first pixel group in the column direction and including a plurality of third unit pixels; and a fourth pixel group disposed adjacent to the third pixel group in the row direction and including a plurality of fourth unit pixels, wherein each of the third unit pixels includes a third optical filter; and each of the fourth unit pixels includes the first optical filter.

In accordance with another embodiment of the disclosed technology, an image sensing device may include: a first pixel group including a plurality of first transfer transistors arranged in two rows and two columns; and a second pixel group including a plurality of second transfer transistors arranged in another two rows and another two columns and disposed adjacent to the first pixel group in a row direction, wherein two second transfer transistors located in a second direction with respect to a center of the second pixel group are simultaneously activated in response to an activation of two first transfer transistors located in a first direction with respect to a center of the first pixel group, the first direction being perpendicular to the second direction.

In some implementations, the image sensing device may further include a first microlens disposed to overlap the first pixel group; and a second microlens disposed to overlap the second pixel group.

In some implementations, the image sensing device may further include a third pixel group including a plurality of third transfer transistors and disposed adjacent to the first pixel group in a column direction; and a fourth pixel group including a plurality of fourth transfer transistors and disposed to be in contact the third pixel group in the row direction, wherein in response to an activation of two first transfer transistors located in the first direction, two third transfer transistors located in a third direction opposite to the first direction are activated simultaneously, and two fourth transfer transistors located in a fourth direction opposite to the second direction are activated simultaneously.

In some implementations, the image sensing device may further include a third pixel group including a plurality of third transfer transistors and disposed to be in contact with the first pixel group in a column direction; and a fourth pixel group including a plurality of fourth transfer transistors and disposed to be in contact with the third pixel group in the row direction, wherein in response to an activation of two first transfer transistors located in the first direction, two third transfer transistors located in a fourth direction opposite to the second direction are activated simultaneously, and two fourth transfer transistors located in a third direction opposite to the first direction are activated simultaneously.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a diagram illustrating a structure of an image sensing device (ISD) according to embodiments of the disclosed technology.

FIG. 2 is a schematic diagram illustrating an example of a portion of a pixel array according to an embodiment of the disclosed technology.

FIG. 3 is a schematic diagram illustrating an example of a portion of a pixel array according to another embodiment of the disclosed technology.

FIG. 4 is a schematic diagram illustrating an example of a portion of a pixel array according to another embodiment of the disclosed technology.

FIG. 5 is a schematic diagram illustrating an example of a portion of a pixel array according to still another embodiment of the disclosed technology.

FIG. 6 is a circuit diagram illustrating an example of an equivalent circuit of a first pixel group PG1 shown in FIG. 2 according to embodiments of the disclosed technology.

FIG. 7 is a timing diagram illustrating operations of example transfer control signals provided to the pixel array shown in FIG. 2 according to embodiments of the disclosed technology.

### DETAILED DESCRIPTION

This patent document provides implementations and examples of an image sensing device that may be used in configurations to substantially address one or more technical or engineering issues and to mitigate limitations or disadvantages encountered in some other image sensing devices. Some implementations of the disclosed technology relate to an image sensing device capable of generating image data and phase data. Some implementations of the disclosed technology relate to an image sensing device capable of generating phase data without outputting additional pixel signals using pixel signals generated by a plurality of unit pixels included in a pixel array. The disclosed technology may provide the image sensing device that can generate image data and phase data based on pixel signals output from a pixel array. The disclosed technology may provide the image sensing device that can generate phase data based on pixel signals output from the pixel array and can perform a phase-difference detection autofocus (PDAF) function using the generated phase data.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

In the following description, a detailed description of related known configurations or functions incorporated herein will be omitted to avoid obscuring the subject matter.

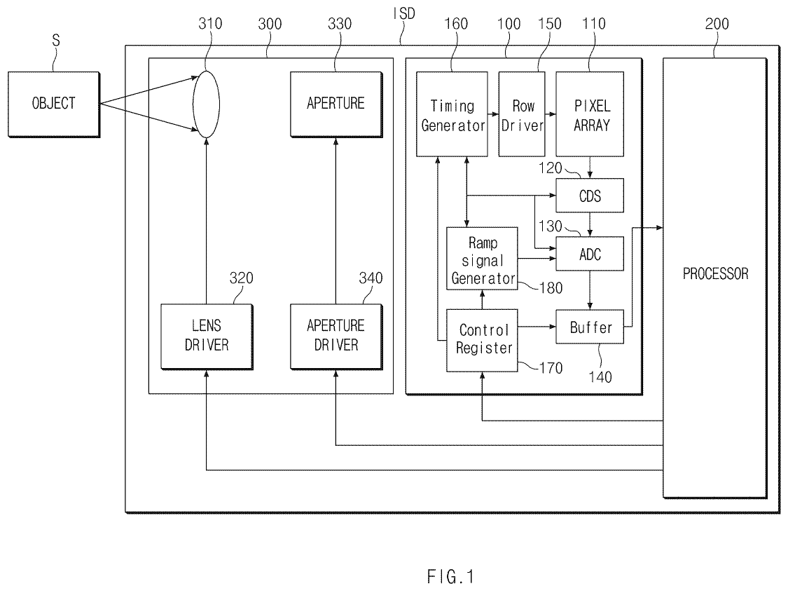

FIG. 1 is a block diagram illustrating an example of an image sensing device ISD based on some implementations of the disclosed technology. A method for performing an autofocus (AF) function by the image sensing device ISD and a method for generating image data by the image sensing device ISD will hereinafter be described with reference to FIG. 1.

Referring to FIG. 1, the image sensing device ISD may include an imaging circuit 300, an image sensor 100, and a processor 200.

The imaging circuit 300 may be a component that receives light. In more detail, the imaging circuit 300 may include a lens 310, a lens driver 320, an aperture 330, and an aperture driver 340.

The lens 310 may refer not only to a single lens, but also to a configuration including a plurality of lenses.

The lens driver 320 may control the position of the lens 310 according to a control signal of a processor 200. As the position of the lens 310 is adjusted, the distance between the lens 310 and the target object (S) may also be adjusted.

The aperture 330 may adjust the amount of light to be incident upon the lens 310 based on a control signal from the aperture driver 340. As the amount of light (i.e., the amount of reception light) to be incident upon the lens 310 is adjusted through the aperture 330, the magnitude of signals generated by the image sensor 100 can also be adjusted in response to the adjusted amount of light.

The aperture driver 340 may control the aperture 330, such that the aperture driver 340 can adjust the amount of light to be incident upon the lens 310 using the aperture 330.

The processor 200 may transmit a signal for adjusting the position of the lens 310 to the lens driver 320 based on a signal generated by the image sensor 100, or may transmit a signal for adjusting a value of the aperture 330 to the aperture driver 340.

The image sensor 100 may include a pixel array 110, a correlated double sampler (CDS) 120, an analog-digital converter (ADC) 130, a buffer 140, a row driver 150, a timing generator 160, a control register 170, and a ramp signal generator 180.

In some implementations, the pixel array 110 may include at least one unit pixel. Here, the pixel group may include four unit pixels arranged in a (2×2) matrix.

Incident light (optical signal) having passed through the lens 310 and the aperture 330 may be imaged by the pixel array 110 and converted into an electrical signal. Unit pixels may respectively generate electrical signals corresponding to an external object (S).

The photoelectric conversion elements of unit pixels included in the pixel array 110 may absorb light to generate charges, and may provide an electrical signal for the generated charges to the correlated double sampler (CDS) 120.

Each unit pixel included in the pixel array 110 may include a microlens, an optical filter, a photoelectric conversion element, and an interconnect layer (also called a “wiring layer”). According to an embodiment, unit pixels included in the same pixel group may overlap at least a portion of one microlens. Additionally, each of the unit pixels included in the same pixel group may include an optical filter that transmits light of the same wavelength.

The microlens may allow light incident upon the pixel array 110 to converge upon the optical filter and the photoelectric conversion element. The optical filter may enable the incident light having penetrated the microlens to selectively pass therethrough according to wavelengths of the incident light.

Each unit pixel may include a photoelectric conversion element corresponding to incident light.

The photoelectric conversion element may generate photocharges corresponding to incident light that has penetrated the microlens and the optical filter. Each of the photoelectric conversion elements may be implemented as a photodiode, a phototransistor, a photogate, a pinned photodiode (PPD), or a combination thereof. For convenience of description, it is assumed that each photoelectric conversion element is implemented as a photodiode as an example.

If the photoelectric conversion element is a photodiode, the photoelectric conversion element may include a stacked structure in which an N-type impurity region and a P-type impurity region are vertically stacked. The photoelectric conversion element may be formed in a semiconductor substrate. For example, the semiconductor substrate may be a P-type semiconductor substrate.

The interconnect layer may be disposed below the photoelectric conversion element. Here, the interconnect layer may also be called a wiring layer as needed. The interconnect layer may include a reset transistor, a transfer transistor, a floating diffusion (FD) region, a drive transistor, a selection transistor, etc.

The reset transistor may be activated in response to a reset control signal, such that the reset transistor may reset the potential of each unit pixel to a predetermined voltage level (e.g., a pixel voltage level).

In addition, when the reset transistor is activated, the transfer transistor may also be activated to reset the floating diffusion (FD) region.

Since the transfer transistor is activated in response to a transfer control signal, the transfer transistor can transmit photocharges accumulated in the photoelectric conversion element of each pixel to the floating diffusion (FD) region.

According to an embodiment, each unit pixel may include a transfer transistor corresponding to a photoelectric conversion element, and a pixel group including a plurality of unit pixels may include a plurality of transfer transistors.

The floating diffusion (FD) region may receive and accumulate charges generated by the photoelectric conversion element. The floating diffusion (FD) region may be connected to a gate electrode of the drive transistor.

Each pixel group may include one floating diffusion (FD) region. More specifically, the floating diffusion (FD) region may be shared by the unit pixels included in the pixel group.

The drive transistor may receive a pixel voltage through a drain electrode thereof, and may be coupled to the floating diffusion (FD) region through a gate electrode thereof. In addition, the drive transistor may be coupled to the selection transistor through a source electrode thereof.

The drive transistor may output a current corresponding to the voltage of the floating diffusion (FD) region coupled to a gate electrode thereof to a signal line through the selection transistor. In other words, the voltage in the floating diffusion (FD) region can be amplified through the drive transistor.

The selection transistor may be activated in response to a selection control signal applied to a gate electrode thereof, such that the selection transistor may transmit an output signal of the drive transistor to the signal line. The pixel signal applied to the signal line may be provided to the correlated double sampler (CDS) 120.

Signals output from the pixel array 110 in response to charges accumulated in the floating diffusion (FD) region included in the pixel array 110 may be referred to as pixel signals.

The correlated double sampler (CDS) 120 may sample and hold electrical signals received from the pixel array 110. The correlated double sampler (CDS) 120 may perform double sampling of a signal level caused by incident light and a specific noise level, and may thus output a signal level corresponding to a difference between the sampling resultant signals. Noise in the pixel signal may be removed by the correlated double sampler (CDS) 120.

The analog-to-digital converter (ADC) 130 may convert the received analog signal into a digital signal, and may transmit the digital signal to the buffer 140.

The buffer 140 may latch the received digital signals, and may sequentially output the latched digital signals to the processor 200. The buffer 140 may include a memory for latching the digital signal and a sense amplifier for amplifying the digital signal.

The row driver 150 may drive the plurality of unit pixels contained in the pixel array 110 in response to an output signal of the timing generator 160.

For example, the row driver 150 may generate signals (e.g., a transfer control signal for controlling the transfer transistor, a reset control signal for controlling the reset transistor, a selection control signal for controlling the selection transistor, and the like) for controlling transistors included in the plurality of unit pixels included in the pixel array 110, and may provide the generated signals to the pixel array 110.

The row driver 150 may determine activation and deactivation time points of the transfer control signal, the reset control signal, and the selection control signal to be provided to the unit pixels included in each of the plurality of pixel groups.

According to an embodiment, one transfer control signal to be provided by the row driver 150 to the pixel array 110 may be simultaneously provided to a plurality of unit pixels located in different row lines.

In some implementations, the transfer control signal line through which the row driver 150 provides the transfer control signal may be simultaneously connected to a plurality of unit pixels located in different row lines.

The row driver 150 may adjust the activation time point of the transfer control signal provided to the pixel array 110, so that pixel signals output from each pixel group may correspond to different phases. By simultaneously outputting pixel signals corresponding to different phases, pixel signal calculation for phase data calculation can be simplified.

The timing generator 160 may cause the pixel array 110 to absorb light and accumulate charges, or may temporarily store the accumulated charges. In addition, the timing generator 160 may control the row driver 150 to output an electrical signal corresponding to the stored charges to the outside of the pixel array 110. An electrical signal, that is output to the outside of the pixel array 110 and corresponds to each unit pixel or each pixel group, may hereinafter be referred to as a pixel signal.

In some implementations, the timing generator 160 may control the correlated double sampler (CDS) 120 to sample and hold the pixel signal provided by the pixel array 110. The timing generator 160 may control the analog-to-digital converter (ADC) 130 to convert the signal received from the correlated double sampler (CDS) 120 into a digital signal.

The control register 170 may generate and store control signals for controlling the buffer 140, the timing generator 160, and the ramp signal generator 180 based on signals received from the processor 200.

The ramp signal generator 180 may generate a ramp signal to be compared with the pixel signal. The ramp signal generator 180 may provide a ramp signal to the correlated double sampler (CDS) 120 in response to a control signal of the timing generator 160, and the correlated double sampler (CDS) 120 may compare the pixel signal caused by incident light with the ramp signal by using the ramp signal as a reference signal, and may output a result of comparison.

The processor 200 may receive a digital signal output from the buffer 140 and may generate image data or phase difference data. In addition, as described above, the processor 200 may provide a control signal to the aperture driver 340 using the generated image data. Additionally, the processor 200 may provide a control signal to the lens driver 320 using phase difference data.

For example, the processor 200 may perform various processes, for example, noise reduction, gain adjustment, waveform shaping, interpolation, a white balance process, a gamma process, and/or an edge sharpening process, etc.

In some implementations, the processor 200 may calculate a phase difference used in the autofocus (AF) operation based on phase data.

The processor 200 may receive the output signal of the buffer 140 and may generate phase difference data or image data.

For example, an operation mode in which the processor 200 generates phase difference data may be referred to as a first mode.

In an embodiment, during the first mode, the processor 200 may generate phase difference data for the external object (S) using signals generated from a plurality of unit pixels included in different pixel groups.

A plurality of pixel groups adjacent to each other in the row or column direction of the pixel array may output pixel signals corresponding to different phases.

For example, when a pixel group includes four unit pixels arranged in a (2×2) matrix including two rows and two columns, first to fourth phase signals are obtained from different combinations of two unit pixels based on locations of the unit pixels. For example, a pixel signal output from a pair of two unit pixels located upward with respect to the center of a pixel group including four unit pixels arranged in a (2×2) matrix may be referred to as a first phase signal. A pixel signal output from a pair of two unit pixels located to the left of the center of the pixel group may be referred to as a second phase signal. A pixel signal output from a pair of two unit pixels located downward with respect to the center of the pixel group may be referred to as a third phase signal. A pixel signal output from a pair of two unit pixels located to the right of the center of the pixel group may be referred to as a fourth phase signal.

The processor 200 may generate phase data for the object (S) based on the first to fourth phase signals.

If the distance between the lens 310 and the object (S) is considered to correspond to an “in-focus position”, incident lights that have reached the respective unit pixels after passing through one microlens may have the same magnitude, such that signals respectively detected by the unit pixels sharing one microlens may have the same magnitude.

Therefore, when the distance between the lens 310 and the object (S) satisfies the in-focus position, the first phase signal and the third phase signal collected by the processor 200 may have the same magnitude, and the second phase signal and the fourth phase signal may have the same magnitude.

On the other hand, when the distance between the lens 310 and the object (S) does not satisfy the in-focus position, incident light having reached the unit pixels may be different in intensity (e.g., magnitude) from each other. In this case, different intensities of light may reach the respective unit pixels.

This is because paths to arrive for the incident light beams to the unit pixels are different from each other after the incident light passes through one microlens. Therefore, when the distance between the lens 310 and the object (S) does not satisfy the in-focus position, the first phase signal and the third phase signal collected by the processor 200 may be different in magnitude from each other, and the second phase signal and the fourth phase signal may also be different in magnitude from each other.

If the distance between the lens 310 and the object (S) does not satisfy the in-focus position, the processor 200 may calculate a difference in magnitude between the phase signals, and may thus generate phase difference data based on the calculated difference.

The processor 200 may adjust a distance between the object (S) and the lens 310 and a distance between the pixel array 110 and the lens 310 by providing a control signal to the lens driver 320 based on the phase difference data.

By way of example, the operation mode in which the processor 200 generates image data may be referred to as a second mode.

Image data may be data generated in response to light that is reflected from the object (S) and then incident upon the image sensor 100, and may be used as a signal to adjust a value of the aperture 330.

The processor 200 may obtain an image signal corresponding to each pixel group from pixel signals output from all unit pixels included in an arbitrary pixel group.

The processor 200 may generate image data for the external object (S) based on the output signal of the buffer 140 corresponding to all unit pixels included in each pixel group.

During the second mode, the processor 200 may generate image data using signals generated from four unit pixels sharing one microlens.

The processor 200 may perform a variety of image signal processing to improve image quality, such as noise correction (or noise cancellation) of image information, interpolation between adjacent pixels, etc.

Although the processor 200 shown in FIG. 1 is located outside the image sensor 100 for convenience of description, the processor 200 can be located inside the image sensor 100 or can be separately located outside the image sensing device (ISD).

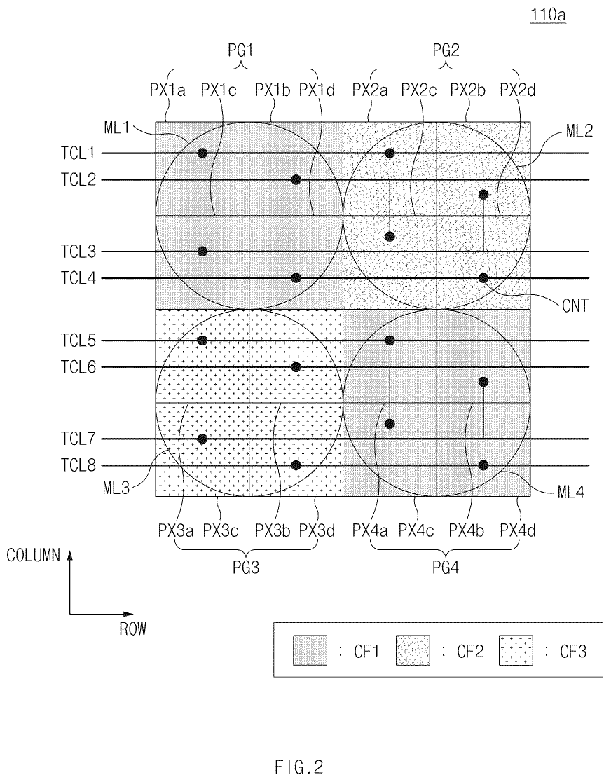

FIG. 2 is a schematic diagram illustrating an example of a portion of the pixel array according to an embodiment of the disclosed technology.

Referring to FIG. 2, the pixel array portion 110a may include a plurality of pixel groups such as PG1, PG2, PG3, and PG4 as illustrated, and each pixel group (e.g., PG1) may include four or more adjacent unit pixels in an array, e.g., four adjacent unit pixels PX1a, PX1b, PX1c, PX1d arranged in a (2×2) matrix including two rows and two columns. Each unit pixel may include one photoelectric conversion element that converts incident light into an electrical signal representing the amount of the incident light detected by that unit pixel. This enables the pixel array portion 110a to capture images in the incident light. FIG. 2 shows an example having the first pixel group (PG1), the second pixel group (PG2), the third pixel group (PG3), and the fourth pixel group (PG4) included in the pixel array portion 110a.

Each unit pixel in the pixel array portion 110a (e.g., PX1a) included in each pixel group (e.g., PG1) may be connected to a transfer control signal line (e.g., TCL1). For convenience of description, the connection relationship between a unit pixel (e.g., PX1a) and the corresponding transfer control signal line (e.g., TCL1) may be displayed through a connection unit (CNT). For example the connection unit (CNT) includes TSV (through silicon via) or other types of vertical contacts.

In various implementations, unit pixels in the same pixel group may be implemented with unit pixel optical filters of the same color, such as the illustrated four unit pixels (e.g., PX1a, PX1b, PX1c, PX1d) included in one pixel group (e.g., PG1) may include the same color filters (e.g., CF1). In various implementations of imaging devices for capturing color images, adjacent pixel groups may be configured with unit pixels with different color filters so that one pixel group is configured to detect incident light in one color and another adjacent pixel group is configured to detect incident light in another different color. For example, a Bayer filter pattern may be implemented to have adjacent different color filters with 50% in green, 25% in red and 25% in blue to capture colored images. Accordingly, adjacent pixel groups may be designed based on the Bayer filter pattern to capture color images in the incident light.

For example, each unit pixel (e.g., PX1a) may include an optical filter to allow light at a desired color to be transmitted through that optical filter to be detected, e.g., at least one of a first optical filter (CF1) for transmitting light in a first color while blocking transmission of light in other colors, a second optical filter (CF2) for transmitting light in a second color while blocking transmission of light in the first color and other colors, or a third optical filter (CF3) for transmitting light in a third color while blocking transmission of light in the first and second colors and other colors.

In the example in FIG. 2, under the above Bayer filter pattern, each of the four first unit pixels (PX1a, PX1b, PX1c, PX1d) included in the first pixel group (PG1) may be a first optical filter (CF1) which may be a green color filter that selectively transmits green light, each of the four second unit pixels (PX2a, PX2b, PX2c, PX2d) included in the second pixel group (PG2) may include a second optical filter (CF2) which may be a blue color filter that selectively transmits blue light, and each of the four third unit pixels (PX3a, PX3b, PX3c, PX3d) included in the third pixel group (PG3) may include a third optical filter (CF3) which may be a red color filter that selectively transmits red light. In addition, each of the four fourth unit pixels (PX4a, PX4b, PX4c, PX4d) included in the fourth pixel group (PG4) may include the same first optical filter (CF1) as in each unit pixel in the first pixel group PG1.

In some implementations, the pixel groups (PG1, PG2, PG3, PG4) included in a portion of the pixel array (hereinafter referred to as “pixel array portion 110a”) may overlap the microlenses (ML1, ML2, ML3, ML4), respectively, such that different unit pixels included in one pixel group may share one common microlens for that pixel group. For example, as shown in the example in FIG. 2, the microlens ML1 in the pixel group PG1 is shared by the constituting four unit pixels PX1a, PX1b, PX1c, PX1d in the context that incident light is directed by the microlens ML1 to the four unit pixels PX1a, PX1b, PX1c, PX1d.

Each of the four first unit pixels (PX1a, PX1b, PX1c, PX1d) included in the first pixel group (PG1) may overlap at least a portion of the first microlens ML1. Additionally, each of the first unit pixels (PX1a, PX1b, PX1c, PX1d) may include a first optical filter (CF1). The first optical filter (CF1) may be a green color filter that selectively transmits green light.

Referring to FIG. 2, any one (PX1a) of the two first unit pixels (PX1a, PX1b) located upward with respect to the center of the first pixel group (PG1) may be connected to a first transfer control signal line (TCL1), and the other one (PX1b) from among the two first unit pixels (PX1a, PX1b) located upward with respect to the center of the first pixel group (PG1) may be connected to a second transfer control signal line (TCL2).

In addition, the first transfer control signal line (TCL1) may be connected to any one (PX2a) from among two second unit pixels (PX2a, PX2c) that are included in the second pixel group (PG2) contacting the first pixel group (PG1) in the row direction (ROW) and at the same time are located to the left of the center of the second pixel group (PG2). The second transfer control signal line (TCL2) may be connected to the other one (PX2c) from among the two second unit pixels (PX2a, PX2c) located to the left of the center of the second pixel group (PG2).

Any one (PX1c) of the two first unit pixels (PX1c, PX1d) located downward with respect to the center of the first pixel group (PG1) may be connected to a third transfer control signal line (TCL3), and the other one (PX1d) from among the two first unit pixels (PX1c, PX1d) located downward with respect to the center of the first pixel group (PG1) may be connected to a fourth transfer control signal line (TCL4).

The third transfer control signal line (TCL3) may be connected to any one (PX2b) from among two second unit pixels (PX2b, PX2d) that are included in the second pixel group (PG2) contacting the first pixel group (PG1) in the row direction (ROW) and at the same time are located to the right of the center of the second pixel group (PG2). The fourth transfer control signal line (TCL4) may be connected to the other one (PX2d) from among the two second unit pixels (PX2b, PX2d) located to the right of the center of the second pixel group (PG2).

The third pixel group (PG3) may be in contact with the first pixel group (PG1) in the column direction (COLUMN). A fifth transfer control signal line (TCL5) may be connected to any one (PX3a) from among two third unit pixels (PX3a, PX3b) located upward with respect to the center of the third pixel group (PG3). A sixth transfer control signal line (TCL6) may be connected to the other one (PX3b) from among the two third unit pixels (PX3a, PX3b) located upward with respect to the center of the second pixel group (PG2).

In addition, the fifth transfer control signal line (TCL5) may be connected to any one (PX4a) from among two fourth unit pixels (PX4a, PX4c) that are included in the fourth pixel group (PG4) contacting the third pixel group (PG3) in the row direction (ROW) and at the same time are located to the left of the center of the fourth pixel group (PG4). The sixth transfer control signal line (TCL6) may be connected to the other one (PX4c) from among the two fourth unit pixels (PX4a, PX4c) located to the left of the center of the fourth pixel group (PG4).

Any one (PX3c) of the two third unit pixels (PX3c, PX3d) located downward with respect to the center of the third pixel group (PG3) may be connected to a seventh transfer control signal line (TCL7), and the other one (PX3d) from among the two third unit pixels (PX3c, PX3d) located downward with respect to the center of the third pixel group (PG3) may be connected to an eighth transfer control signal line (TCL8).

The seventh transfer control signal line (TCL7) may be connected to any one (PX4b) from among two fourth unit pixels (PX4b, PX4d) that are included in the fourth pixel group (PG4) contacting the third pixel group (PG3) in the row direction (ROW) and at the same time are located to the right of the center of the fourth pixel group (PG4). The eighth transfer control signal line (TCL8) may be connected to the other one (PX4d) from among the two fourth unit pixels (PX4b, PX4d) located to the right of the center of the fourth pixel group (PG4).

Transfer control signal lines may be connected to gate electrodes of transfer transistors included in each unit pixel. The row driver 150 of FIG. 1 may provide a transfer control signal having an activation voltage level or a deactivation voltage level to each of the transfer transistors through a transfer control signal line.

When a transfer control signal having an activation voltage level is provided to the transfer transistor, photocharges of the photoelectric conversion element included in the unit pixel may move to the floating diffusion (FD) region through the activated transfer transistor.

Therefore, when a first transfer control signal having an activation voltage level is provided to the first transfer control signal line (TCL1) and a second transfer control signal having an activation voltage level is provided to the second transfer control signal line (TCL2), the first transfer transistors included in two first unit pixels (PX1a, PX1b) located upward with respect to the center of the first pixel group (PG1) from among the first unit pixels included in the first pixel group (PG1) may be activated. At this time, among the second unit pixels included in the second pixel group (PG2), the two second unit pixels (PX2a, PX2c) located to the left of the center of the second pixel group (PG2) can be activated at the same point in time.

When the first transfer control signal having an activation voltage level is provided to the first transfer control signal line (TCL1) and the second transfer control signal having an activation voltage level is provided to the second transfer control signal line (TCL2), a seventh transfer control signal having an activation voltage level may be provided to the transfer control signal line (TCL7), and an eighth transfer control signal having an activation voltage level may be provided to the eighth transfer control signal line (TCL8).

When the seventh transfer control signal having an activation voltage level is provided to the seventh transfer control signal line (TCL7) and the eighth transfer control signal having an activation voltage level is provided to the eighth transfer control signal line (TCL8), the third transfer transistors included in two third unit pixels (PX3c, PX3d) located downward with respect to the center of the third pixel group (PG3) from among the third unit pixels included in the third pixel group (PG3) can be activated. At this time, among the fourth unit pixels included in the fourth pixel group (PG4), two fourth unit pixels (PX4b, PX4d) located to the right of the center of the fourth pixel group (PG4) can be activated at the same point in time.

The row driver 150 included in the image sensor 100 may simultaneously provide the transfer control signal having an activation voltage level through the first transfer control signal line (TCL1), the second transfer control signal line (TCL2), the seventh transfer control signal line (TCL7), and the eighth transfer control signal line (TCL8). As a result, the row driver 150 can simultaneously obtain a pixel signal output from two unit pixels (PX1a, PX1b) located upward with respect to the center of each pixel group (PG1, PG2, PG3, PG4), a pixel signal output from two unit pixels (PX3c, PX3d) located downward with respect to the center of each pixel group (PG1, PG2, PG3, PG4), a pixel signal output from two unit pixels (PX2a, PX2c) located to the left of the center of each pixel group (PG1, PG2, PG3, PG4), and a pixel signal output from two unit pixels (PX4b, PX4d) located to the right of the center of each pixel group (PG1, PG2, PG3, PG4).

As described with reference to FIG. 1, a pixel signal output from two unit pixels located upward with respect to the center of an arbitrary pixel group may be referred to as a first phase signal, and a pixel signal output from two unit pixels located downwards with respect to the center of the arbitrary pixel group may be referred to as a third phase signal. Additionally, a pixel signal output from the two unit pixels located to the left of the center of the arbitrary pixel group may be referred to as a second phase signal, and a pixel signal output from the two unit pixels located to the right of the center of the arbitrary pixel group may be referred to as a fourth phase signal.

The image sensor 100 according to an embodiment of the disclosed technology may be configured such that the transfer control signals are commonly connected to the unit pixels that are included in different pixel groups and located in different rows.

By the connection layout of the transfer control signal lines as suggested in the implementations of the disclosed technology, the image sensor 100 can simultaneously acquire the first phase signal, the second phase signal, the third phase signal, and the fourth phase signal.

In the conventional art, the respective transfer control signal lines may be commonly connected to the plurality of unit pixels located in the same row of the pixel array.

For example, in the conventional image sensor, the first transfer control signal line (TCL1) may be connected to the first unit pixel (PX1a) located at a first-row-and-first-column position of the first pixel group (PG1), and may be connected to the second unit pixel (PX2A) located at a first-row-and-first-column position of the second pixel group (PG2). In addition, in the conventional image sensor, the second transfer control signal line (TCL2) may be connected to the first unit pixel (PX1b) located at a first-row-and-second-column position of the first pixel group (PG1), and may be connected to the second unit pixel (PX2b) located at a first-row-and-second-column position of the second pixel group (PG2).

In the conventional image sensor, by applying the transfer control signals each having an activation voltage level to the first transfer control signal line (TCL1) and the second transfer control signal line (TCL2), the first phase signal may be output from the first pixel group (PG1) and the second phase signal may be output from the second pixel group (PG2) located in the row direction with respect to the first pixel group (PG1). Thus, the same first phase signal are output from the first and second pixel groups that are adjacent to each other in the row direction.

In the conventional image sensor, since the same phase signals are output from two pixel groups adjacent to each other in the row direction, a separate calculation process may be required to collect the first to fourth phase signals.

For example, the conventional image sensor may provide transfer control signals each having an activation voltage level to the first to fourth transfer control signal lines (TCL1, TCL2, TCL3, TCL4), so that the conventional image sensor can collect pixel signals corresponding to all unit pixels included in the first pixel group (PG1).

The conventional image sensor may obtain a phase signal (i.e., a third phase signal) corresponding to two unit pixels located in a downward direction from the center of the pixel group based on a difference between the first phase signal and the pixel signals corresponding to the entire unit pixels included in the first pixel group (PG1).

Accordingly, the conventional image sensor requires an additional calculation process to obtain all of the first to fourth phase signals, and thus much more time is required to generate phase data.

In addition, the conventional image sensor obtains the remaining phase signals based on a difference between the arbitrary phase signal and the pixel signals corresponding to the entire unit pixels included in the pixel group, so that the additional capacity of the floating diffusion (FD) region is required for phase signal calculation.

The conventional image sensor outputs a pixel signal by accumulating photocharges for all unit pixels included in each pixel group, and obtains the remaining phase signals by subtracting an arbitrary phase signal from the pixel signal. As a result, in order to accurately output a pixel signal corresponding to photocharges exceeding a saturation illuminance, the conventional image sensor is required to secure the additional capacity of the floating diffusion (FD) region.

Unlike the conventional image sensor, since the image sensor 100 based on some implementations of the disclosed technology can simultaneously collect a plurality of phase signals, there is no need to secure the capacity of the floating diffusion (FD) region to output a pixel signal exceeding the saturation illuminance.

Therefore, the image sensor 100 based on some implementations of the disclosed technology can reduce the size of the floating diffusion (FD) region compared to the conventional image sensor, and can secure a space in which the photoelectric conversion element(s) or pixel transistor(s) can be arranged according to the reduction in size of the floating diffusion (FD) region.

The conventional image sensor can only obtain the same phase signal from pixel groups located in the same row of the pixel array, so that the conventional image sensor cannot collect the first to fourth phase signals at the same time.

Unlike the conventional image sensor, the image sensing device 100 based on some implementations of the disclosed technology may commonly connect one transfer control signal line to unit pixels located in different rows, so that the phase signals collected from the pixel groups adjacent to each other in the row direction can be arranged perpendicular to each other.

Unlike the conventional image sensor, the image sensor 100 based on some implementations of the disclosed technology can collect the first to fourth phase signals at the same point in time by changing the connection layout of the transfer control signal line, thereby enabling rapid phase data calculation.

The processor 200 (see FIG. 1) may calculate phase data for the object (S) based on the first to fourth phase signals. In particular, the image sensing device (ISD) based on some implementations of the disclosed technology may generate phase data by calculating both a vertical phase difference for the object (S) and a horizontal phase difference for the object (S).

When transfer control signals each having an activation voltage level are provided to the first to eighth transfer control signal lines (TCL1, TCL2, TCL3, TCL4, TCL5, TCL6, TCL7, TCL8), the processor 200 (see FIG. 1) may generate image data based on pixel signals output for each pixel group (PG1, PG2, PG3, PG4).

The structure of the pixel array portion 110a shown in FIG. 2 may be referred to as a quad-Bayer structure, without being limited thereto. The first optical filter (CF1) may be an optical filter that selectively transmits cyan light, the second optical filter (CF2) may be an optical filter that selectively transmits magenta light, and the third optical filter (CF3) may be an optical filter that selectively transmits yellow light.

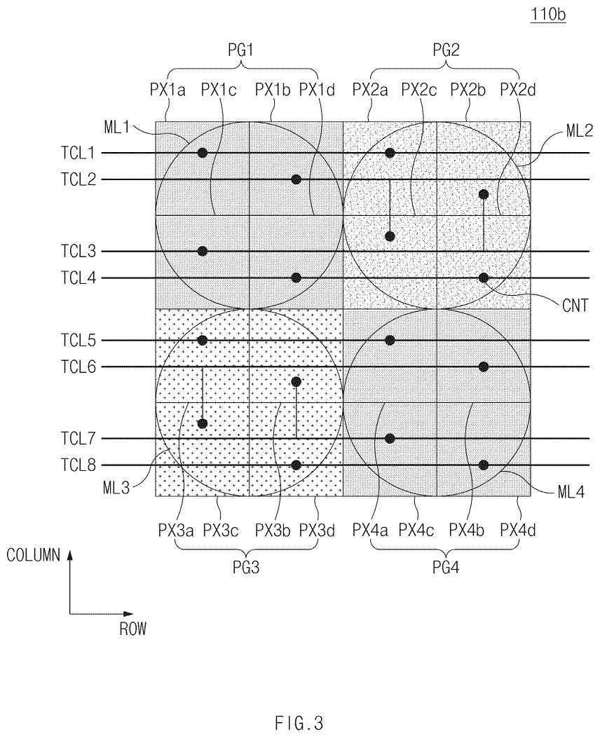

FIG. 3 is a schematic diagram illustrating an example of a portion of the pixel array according to another embodiment of the disclosed technology.

FIG. 3 shows an example of the connection layout of transfer control signal lines according to another embodiment of the disclosed technology.

The remaining characteristics except for the connection relationship between the transfer control signal lines and the unit pixels have already been described in FIG. 2, and as such redundant description thereof will herein be omitted for brevity.

Referring to the pixel array portion 110b of FIG. 3, a first connection shape in which the first, second, third, and fourth transfer control signal lines (TCL1, TCL2, TCL3, TCL4) are respectively connected to the first unit pixels (PX1a, PX1b, PX1c, PX1d) included in the first pixel group (PG1) and a second connection shape in which the first, second, third, and fourth transfer control signal lines (TCL1, TCL2, TCL3, TCL4) are respectively connected to the second unit pixels (PX2a, PX2b, PX2c, PX2d) included in the second pixel group (PG2) may be the same as those of FIG. 2.

The fifth transfer control signal line (TCL5) may be connected to any one (PX3a) from among the third unit pixels (PX3a, PX3c) located to the left of the center of the third pixel group (PG3), and the other one (PX3c) from among the third unit pixels (PX3a, PX3c) located to the left of the center of the third pixel group (PG3) may be connected to the sixth transfer control signal line (TCL6).

The fifth transfer control signal line (TCL5) may be connected to any one (PX4a) from among the two fourth unit pixels (PX4a, PX4b) that are included in the fourth pixel group (PG4) contacting the third pixel group (PG3) in the row direction (ROW) while being located upward with respect to the center of the fourth pixel group (PG4), and the other one (PX4b) from among the two fourth unit pixels (PX4a, PX4b) located upward with respect to the center of the fourth pixel group (PG4) may be connected to the sixth transfer control signal line (TCL6).

Any one (PX3b) of the two third unit pixels (PX3b, PX3d) located to the right of the center of the third pixel group (PG3) may be connected to the seventh transfer control signal line (TCL7), and the other one (PX3d) from among the two third unit pixels (PX3b, PX3d) located to the right of the center of the third pixel group (PG3) may be connected to the eighth transfer control signal line (TCL8).

The seventh transfer control signal line (TCL7) may be connected to any one (PX4c) from among two fourth unit pixels (PX4c, PX4d) that are included in the fourth pixel group (PG4) contacting the third pixel group (PG3) in the row direction (ROW) and at the same time are located downward with respect to the center of the fourth pixel group (PG4). The eighth transfer control signal line (TCL8) may be connected to the other one (PX4d) from among the two fourth unit pixels (PX4c, PX4d) located downward with respect to the center of the fourth pixel group (PG4).

According to another embodiment of the disclosed technology, when a first transfer control signal having an activation voltage level is provided to the first transfer control signal line (TCL1) and a second transfer control signal having an activation voltage level is provided to the second transfer control signal line (TCL2), the first transfer transistors included in two first unit pixels (PX1a, PX1b) from among the first unit pixels included in the first pixel group (PG1) can be activated. Here, the two first unit pixels (PX1a, PX1b) may be located upward with respect to the center of the first pixel group (PG1). At this time, among the second unit pixels included in the second pixel group (PG2), the two second unit pixels (PX2a, PX2c) located to the left of the center of the second pixel group (PG2) can be activated at the same point in time.

When the first transfer control signal having an activation voltage level is provided to the first transfer control signal line (TCL1) and the second transfer control signal having an activation voltage level is provided to the second transfer control signal line (TCL2), the seventh transfer control signal having an activation voltage level may be provided to the seventh transfer control signal line (TCL7), and the eighth transfer control signal having an activation voltage level may be provided to the eighth transfer control signal line (TCL8).

When the seventh transfer control signal having an activation voltage level is provided to the seventh transfer control signal line (TCL7) and the eighth transfer control signal having an activation voltage level is provided to the eighth transfer control signal line (TCL8), the third transfer transistors included in two third unit pixels (PX3b, PX3d) from among the third unit pixels included in the third pixel group (PG3) can be activated. Here, the two third unit pixels (PX3b, PX3d) may be located to the right of the center of the third pixel group (PG3). At this time, among the fourth unit pixels included in the fourth pixel group (PG4), the two fourth unit pixels (PX4c, PX4d) located downward with respect to the center of the fourth pixel group (PG4) can be activated simultaneously.

The row driver 150 included in the image sensor 100 according to an embodiment of the disclosed technology can simultaneously provide the transfer control signals having the activation voltage level through the first transfer control signal line (TCL1), the second transfer control signal line (TCL2), the seventh transfer control signal line (TCL7), and the eighth transfer control signal line (TCL8). As a result, the row driver 150 can simultaneously obtain a pixel signal output from two unit pixels (PX1a, PX1b) located upward with respect to the center of each pixel group (PG1, PG2, PG3, PG4), a pixel signal output from two unit pixels (PX4c, PX4d) located downward with respect to the center of each pixel group, a pixel signal output from two unit pixels (PX2a, PX2c) located to the left of the center of each pixel group, and a pixel signal output from two unit pixels (PX3b, PX3d) located to the right of the center of each pixel group.

As described in FIG. 1, a pixel signal output from two unit pixels located upward with respect to the center of the arbitrary pixel group may be referred to as a first phase signal, and a pixel signal output from two unit pixels located downward with respect to the center of the arbitrary pixel group may be referred to as a third phase signal. Additionally, a pixel signal output from two unit pixels located to the left of the center of the arbitrary pixel group may be referred to as a second phase signal, and a pixel signal output from two unit pixels located to the right of the center of the arbitrary pixel group may be referred to as a fourth phase signal.

The image sensor 100 may include transfer control signal lines that are commonly connected to the unit pixels included in different pixel groups and located in different rows, so that the first phase signal, the second phase signal, the third phase signal, and the fourth phase signal can be obtained at the same point in time.

The processor 200 may generate phase data for the object (S) based on the first phase signal, the second phase signal, the third phase signal, and the fourth phase signal that are acquired at the same point in time.

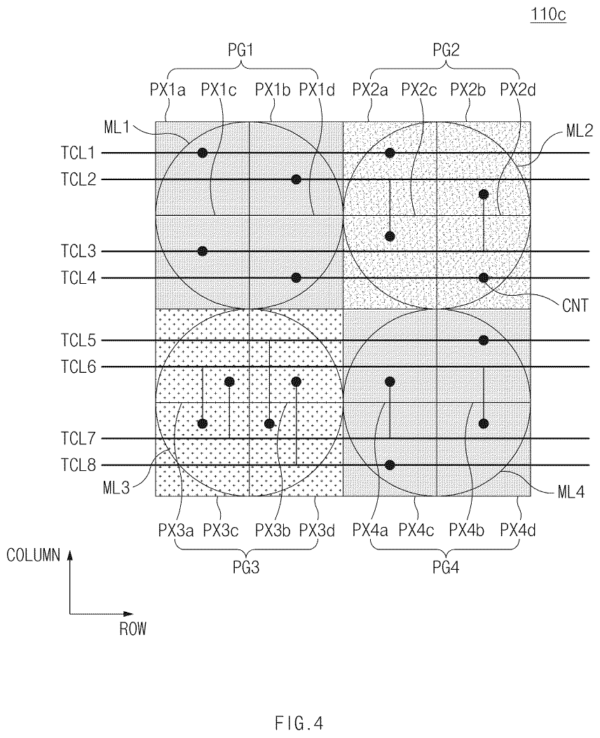

FIG. 4 is a schematic diagram illustrating an example of a portion of the pixel array according to another embodiment of the disclosed technology.

FIG. 4 shows an example of the connection layout of transfer control signal lines according to another embodiment of the disclosed technology.

Referring to the pixel array portion 110c of FIG. 4, a first connection shape in which the first, second, third, and fourth transfer control signal lines (TCL1, TCL2, TCL3, TCL4) are respectively connected to the first unit pixels (PX1a, PX1b, PX1c, PX1d) included in the first pixel group (PG1) and a second connection shape in which the first, second, third, and fourth transfer control signal lines (TCL1, TCL2, TCL3, TCL4) are respectively connected to the second unit pixels (PX2a, PX2b, PX2c, PX2d) included in the second pixel group (PG2) may be the same as those of FIG. 2

In the implementation as shown in FIG. 4, the fifth transfer control signal line (TCL5) may be connected to any one (PX3d) from among the third unit pixels (PX3c, PX3d) located downward with respect to the center of the third pixel group (PG3), and the other one (PX3c) from among the third unit pixels (PX3c, PX3d) located downward with respect to the center of the third pixel group (PG3) may be connected to the sixth transfer control signal line (TCL6).

The fifth transfer control signal line (TCL5) may be connected to any one (PX4b) from among the two fourth unit pixels (PX4b, PX4d) that are included in the fourth pixel group (PG4) contacting the third pixel group (PG3) in the row direction (ROW) while being located to the right of the center of the fourth pixel group (PG4), and the other one (PX4d) from among the two fourth unit pixels (PX4b, PX4d) located to the right of the center of the fourth pixel group (PG4) may be connected to the sixth transfer control signal line (TCL6).

Any one (PX3a) of the two third unit pixels (PX3a, PX3b) located upward with respect to the center of the third pixel group (PG3) may be connected to the seventh transfer control signal line (TCL7), and the other one (PX3b) from among the two third unit pixels (PX3a, PX3b) located upward with respect to the center of the third pixel group (PG3) may be connected to the eighth transfer control signal line (TCL8).

The seventh transfer control signal line (TCL7) may be connected to any one (PX4a) from among two fourth unit pixels (PX4a, PX4c) that are included in the fourth pixel group (PG4) contacting the third pixel group (PG3) in the row direction (ROW) and at the same time are located to the left of the center of the fourth pixel group (PG4). The eighth transfer control signal line (TCL8) may be connected to the other one (PX4c) from among the two fourth unit pixels (PX4a, PX4c) located to the left of the center of the fourth pixel group (PG4).

According to another embodiment of the disclosed technology, when a first transfer control signal having an activation voltage level is provided to the first transfer control signal line (TCL1) and a second transfer control signal having an activation voltage level is provided to the second transfer control signal line (TCL2), the first transfer transistors included in two first unit pixels (PX1a, PX1b) from among the first unit pixels included in the first pixel group (PG1) can be activated. Here, the two first unit pixels (PX1a, PX1b) may be located upward with respect to the center of the first pixel group (PG1). At this time, among the second unit pixels included in the second pixel group (PG2), the two second unit pixels (PX2a, PX2c) located to the left of the center of the second pixel group (PG2) can be activated simultaneously.

When the first transfer control signal having an activation voltage level is provided to the first transfer control signal line (TCL1) and the second transfer control signal having an activation voltage level is provided to the second transfer control signal line (TCL2), the fifth transfer control signal having an activation voltage level may be provided to the fifth transfer control signal line (TCL5), and the sixth transfer control signal having an activation voltage level may be provided to the sixth transfer control signal line (TCL6).

When the fifth transfer control signal having an activation voltage level is provided to the fifth transfer control signal line (TCL5) and the sixth transfer control signal having an activation voltage level is provided to the sixth transfer control signal line (TCL6), the third transfer transistors included in two third unit pixels (PX3c, PX3d) from among the third unit pixels included in the third pixel group (PG3) can be activated. Here, the two third unit pixels (PX3c, PX3d) may be located downward with respect to the center of the third pixel group (PG3). At this time, among the fourth unit pixels included in the fourth pixel group (PG4), the two fourth unit pixels (PX4b, PX4d) located to the right of the center of the fourth pixel group (PG4) can be activated simultaneously.

The row driver 150 included in the image sensor 100 according to an embodiment of the disclosed technology can simultaneously provide the transfer control signals having the activation voltage level through the first transfer control signal line (TCL1), the second transfer control signal line (TCL2), the fifth transfer control signal line (TCL5), and the sixth transfer control signal line (TCL6). As a result, the row driver 150 can simultaneously obtain a pixel signal output from two unit pixels (PX1a, PX1b) located upward with respect to the center of each pixel group (PG1, PG2, PG3, PG4), a pixel signal output from two unit pixels (PX3c, PX3d) located downward with respect to the center of each pixel group, a pixel signal output from two unit pixels (PX2a, PX2c) located to the left of the center of each pixel group, and a pixel signal output from two unit pixels (PX4b, PX4d) located to the right of the center of each pixel group.

As described in FIG. 1, a pixel signal output from two unit pixels located upward with respect to the center of the arbitrary pixel group may be referred to as a first phase signal, and a pixel signal output from two unit pixels located downward with respect to the center of the arbitrary pixel group may be referred to as a third phase signal. Additionally, a pixel signal output from two unit pixels located to the left of the center of the arbitrary pixel group may be referred to as a second phase signal, and a pixel signal output from two unit pixels located to the right of the center of the arbitrary pixel group may be referred to as a fourth phase signal.

The image sensor 100 may include transfer control signal lines that are commonly connected to the unit pixels included in different pixel groups and located in different rows, so that the first phase signal, the second phase signal, the third phase signal, and the fourth phase signal can be obtained at the same point in time.

The processor 200 may generate phase data for the object (S) based on the first phase signal, the second phase signal, the third phase signal, and the fourth phase signal acquired at the same point in time.

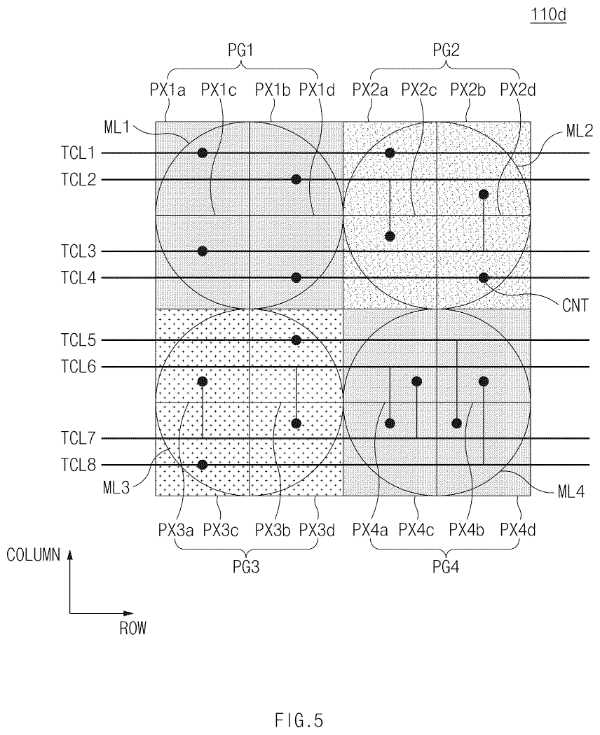

FIG. 5 is a schematic diagram illustrating an example of a portion of the pixel array according to another embodiment of the disclosed technology.

FIG. 5 shows an example of the connection layout of transfer control signal lines according to another embodiment of the disclosed technology.

Referring to the pixel array portion 110d of FIG. 5, a first connection shape in which the first, second, third, and fourth transfer control signal lines (TCL1, TCL2, TCL3, TCL4) are respectively connected to the first unit pixels (PX1a, PX1b, PX1c, PX1d) included in the first pixel group (PG1) and a second connection shape in which the first, second, third, and fourth transfer control signal lines (TCL1, TCL2, TCL3, TCL4) are respectively connected to the second unit pixels (PX2a, PX2b, PX2c, PX2d) included in the second pixel group (PG2) may be the same as those of FIG. 2

The fifth transfer control signal line (TCL5) may be connected to any one (PX3b) from among the third unit pixels (PX3b, PX3d) located to the right of the center of the third pixel group (PG3), and the other one (PX3d) from among the third unit pixels (PX3b, PX3d) located to the right of the center of the third pixel group (PG3) may be connected to the sixth transfer control signal line (TCL6).

The fifth transfer control signal line (TCL5) may be connected to any one (PX4d) from among the two fourth unit pixels (PX4c, PX4d) that are included in the fourth pixel group (PG4) located in the row direction with respect to the third pixel group (PG3) while being located downward with respect to the center of the fourth pixel group (PG4), and the other one (PX4c) from among the two fourth unit pixels (PX4c, PX4d) located downward with respect to the center of the fourth pixel group (PG4) may be connected to the sixth transfer control signal line (TCL6).

Any one (PX3a) of the two third unit pixels (PX3a, PX3c) located to the left of the center of the third pixel group (PG3) may be connected to the seventh transfer control signal line (TCL7), and the other one (PX3c) from among the two third unit pixels (PX3a, PX3c) located to the left of the center of the third pixel group (PG3) may be connected to the eighth transfer control signal line (TCL8).

The seventh transfer control signal line (TCL7) may be connected to any one (PX4a) from among two fourth unit pixels (PX4a, PX4b) that are included in the fourth pixel group (PG4) contacting the third pixel group (PG3) in the row direction (ROW) and at the same time are located upward with respect to the center of the fourth pixel group (PG4). The eighth transfer control signal line (TCL8) may be connected to the other one (PX4b) from among the two fourth unit pixels (PX4a, PX4b) located upward with respect to the center of the fourth pixel group (PG4).

According to another embodiment of the disclosed technology, when the first transfer control signal having an activation voltage level is provided to the first transfer control signal line (TCL1) and the second transfer control signal having an activation voltage level is provided to the second transfer control signal line (TCL2), the first transfer transistors included in two first unit pixels (PX1a, PX1b) from among the first unit pixels included in the first pixel group (PG1) can be activated. Here, the two first unit pixels (PX1a, PX1b) may be located upward with respect to the center of the first pixel group (PG1). At this time, among the second unit pixels included in the second pixel group (PG2), the two second unit pixels (PX2a, PX2c) located to the left of the center of the second pixel group (PG2) can be activated simultaneously.

When the first transfer control signal having an activation voltage level is provided to the first transfer control signal line (TCL1) and the second transfer control signal having an activation voltage level is provided to the second transfer control signal line (TCL2), the fifth transfer control signal having an activation voltage level may be provided to the fifth transfer control signal line (TCL5), and the sixth transfer control signal having an activation voltage level may be provided to the sixth transfer control signal line (TCL6).

When the fifth transfer control signal having an activation voltage level is provided to the fifth transfer control signal line (TCL5) and the sixth transfer control signal having an activation voltage level is provided to the sixth transfer control signal line (TCL6), the third transfer transistors included in two third unit pixels (PX3b, PX3d) from among the third unit pixels included in the third pixel group (PG3) can be activated. Here, the two third unit pixels (PX3c, PX3d) may be located to the right of the center of the third pixel group (PG3). At this time, among the fourth unit pixels included in the fourth pixel group (PG4), the two fourth unit pixels (PX4c, PX4d) located downward with respect to the center of the fourth pixel group (PG4) can be activated simultaneously.

The row driver 150 included in the image sensor 100 according to an embodiment of the disclosed technology can simultaneously provide the transfer control signals having the activation voltage level through the first transfer control signal line (TCL1), the second transfer control signal line (TCL2), the fifth transfer control signal line (TCL5), and the sixth transfer control signal line (TCL6). As a result, the row driver 150 can simultaneously obtain a pixel signal output from two unit pixels (PX1a, PX1b) located upward with respect to the center of each pixel group (PG1, PG2, PG3, PG4), a pixel signal output from two unit pixels (PX4c, PX4d) located downward with respect to the center of each pixel group, a pixel signal output from two unit pixels (PX2a, PX2c) located to the left of the center of each pixel group, and a pixel signal output from two unit pixels (PX3b, PX3d) located to the right of the center of each pixel group.

As described in FIG. 1, a pixel signal output from two unit pixels located upward with respect to the center of the arbitrary pixel group may be referred to as a first phase signal, and a pixel signal output from two unit pixels located downward with respect to the center of the arbitrary pixel group may be referred to as a third phase signal. Additionally, a pixel signal output from two unit pixels located to the left of the center of the arbitrary pixel group may be referred to as a second phase signal, and a pixel signal output from two unit pixels located to the right of the center of the arbitrary pixel group may be referred to as a fourth phase signal.

The image sensor 100 may include transfer control signal lines that are commonly connected to the unit pixels included in different pixel groups and located in different rows, so that the first phase signal, the second phase signal, the third phase signal, and the fourth phase signal can be obtained at the same point in time.

The processor 200 may generate phase data for the object (S) based on the first phase signal, the second phase signal, the third phase signal, and the fourth phase signal acquired at the same point in time.

The connection layout between the transfer control signal lines and the unit pixels shown in FIGS. 2 to 5 is merely an example, and any connection layout in which four different phase signals can be obtained from four pixel groups (PG1, PG2, PG3, PG4) can be included in the technical idea of the disclosed technology.

In some implementations, the shapes of the pixel array portions (110a, 110b, 110c, 110d) shown in FIGS. 2 to 5 may be repeated throughout the pixel array 110.

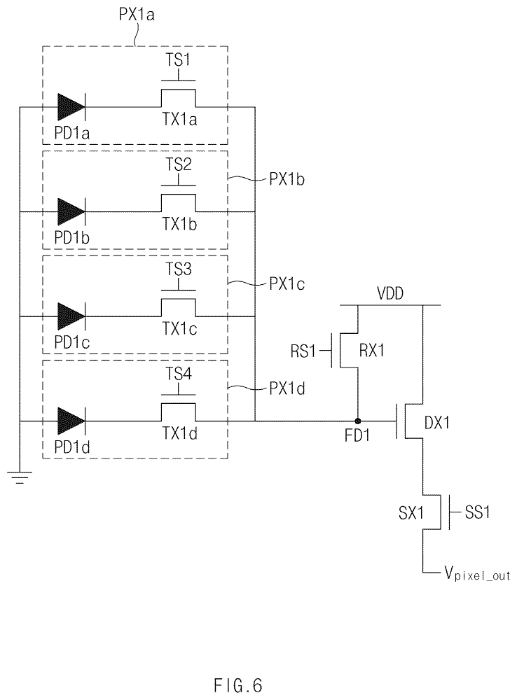

FIG. 6 is a circuit diagram illustrating an example of an equivalent circuit of a first pixel group PG1 shown in FIG. 2 according to embodiments of the disclosed technology.

Referring to FIG. 6, the four first unit pixels (PX1a, PX1b, PX1c, PX1d) included in the first pixel group (PG1) may include the first photoelectric conversion elements (PD1a, PD1b, PD1c, PD1d), respectively.

In some implementations, the first photoelectric conversion elements (PD1a, PD1b, PD1c, PD1d) may be connected to the first transfer transistors (TX1a, TX1b, TX1c, TX1d), respectively.

First to fourth transfer control signals (TS1, TS2, TS3, TS4) may be respectively provided to the first transfer transistors (TX1a, TX1b, TX1c, TX1d) through transfer control signal lines.

The first unit pixel (PX1a) located at a first-row-and-first-column position of the first pixel group (PG1) may include a first transfer transistor (TX1a) to which the first transfer control signal (TS1) is provided. The gate electrode of the first transfer transistor (TX1a) to which the first transfer control signal (TS1) is provided may be connected to the first transfer control signal line TCL1 (see FIG. 2). The first unit pixel (PX1a) located at a first-row-and-first-column position of the first pixel group (PG1) may include a first photoelectric conversion element (PD1a).

The first unit pixel (PX1b) located at a first-row-and-second-column position of the first pixel group (PG1) may include a first transfer transistor (TX1b) to which the second transfer control signal (TS2) is provided. The gate electrode of the first transfer transistor (TX1b) to which the second transfer control signal (TS2) is provided may be connected to the second transfer control signal line TCL2 (see FIG. 2). The first unit pixel (PX1b) located at a first-row-and-second-column position of the first pixel group (PG1) may include a first photoelectric conversion element (PD1b).

The first unit pixel (PX1c) located at a second-row-and-first-column position of the first pixel group (PG1) may include a first transfer transistor (TX1c) to which the third transfer control signal (TS3) is provided. The gate electrode of the first transfer transistor (TX1c) to which the third transfer control signal (TS3) is provided may be connected to the third transfer control signal line TCL3 (see FIG. 2). The first unit pixel (PX1c) located at a second-row-and-first-column position of the first pixel group (PG1) may include a first photoelectric conversion element (PD1c).

The first unit pixel (PX1d) located at a second-row-and-second-column position of the first pixel group (PG1) may include a first transfer transistor (TX1d) to which the fourth transfer control signal (TS4) is provided. The gate electrode of the first transfer transistor (TX1d) to which the fourth transfer control signal (TS4) is provided may be connected to the fourth transfer control signal line TCL4 (see FIG. 2). The first unit pixel (PX1d) located at a second-row-and-second-column position of the first pixel group (PG1) may include a first photoelectric conversion element (PD1d).

Each of the first transfer transistors (TX1a, TX1b, TX1c, TX1d) has a first terminal and a second terminal. The first photoelectric conversion elements (PD1a, PD1b, PD1c, PD1d) may be connected to first terminals of the first transfer transistors (TX1a, TX1b, TX1c, TX1d), and the first floating diffusion region (FD1) may be connected to second terminals of the first transfer transistors (TX1a, TX1b, TX1c, TX1d). The first floating diffusion region (FD1) may be commonly connected to the four first transfer transistors (TX1a, TX1b, TX1c, TX1d).

Photocharges can move from the first photoelectric conversion elements (PD1a, PD1b, PD1c, PD1d) to the first floating diffusion region (FD1) based on voltage levels of the first to fourth transfer control signals (TS1, TS2, TS3, TS4) respectively applied to the first transfer transistors (TX1a, TX1b, TX1c, TX1d).

The first floating diffusion region (FD1) may be connected to one terminal of the first reset transistor (RX1). The pixel voltage (VDD) may be connected to the other terminal of the first reset transistor (RX1), and a reset operation for the first pixel group (PG1) may be performed according to the voltage level of a first reset control signal (RS1).

The first floating diffusion region (FD1) may be connected to the gate electrode of the first drive transistor (DX1). The voltage of the first floating diffusion region (FD1) may be amplified by the first drive transistor (DX1).

The first selection transistor (SX1) contacting one side of the first drive transistor (DX1) may determine whether to output the pixel signal (Vpixel_out) corresponding to a voltage change amplified by the first drive transistor (DX1). Whether or not to output the pixel signal (Vpixel_out) may be determined depending on the voltage level of a first selection control signal (SS1).

For the first mode in which the processor 200 generates phase difference data, each of the first transfer control signal (TS1) and the second transfer control signal (TS2) may have an activation voltage level.

At this time, photocharges may move from the first photoelectric conversion element (PD1a) included in the first unit pixel (PX1a) located at the first-row-and-first-column position of the first pixel group (PG1) toward the first floating diffusion region (FD1). Photocharges may move from the first photoelectric conversion element (PD1b) included in the first unit pixel (PX1b) located in the first-row-and-second-column position of the first pixel group (PG1) toward the first floating diffusion region (FD1).

In this implementation, photocharges generated in the two first unit pixels (PX1a, PX1b) located upward with respect to the center of the first pixel group (PG1) may move to the first floating diffusion region (FD1).

Photocharges corresponding to the two first unit pixels (PX1a, PX1b) located upward with respect to the center of the first pixel group (PG1) may move to the first floating diffusion region (FD1), and may be output as a pixel signal (Vpixel_out) after passing through the first drive transistor (DX1) and the first selection transistor (SX1).

The first floating diffusion region FD1 is provided with a photocharge corresponding to two first unit pixels (PX1a, PX1b) positioned above the center of the first pixel group PG1, and a pixel signal (Vpixel_out) may be output through the first drive transistor DX1 and the first selection transistor SX.

At this time, the output pixel signal may be a first phase signal that is output from a pair of two unit pixels located upward with respect to the center of the pixel group.

For the second mode in which the processor 200 generates image data, each of the first transfer control signal (TS1), the second transfer control signal (TS2), the third transfer control signal (TS3), and the fourth transfer control signal (TS4) may have an activation voltage level.

At this time, photocharges may move from the first photoelectric conversion elements (PD1a, PD1b, PD1c, PD1d) respectively included in the first unit pixels (PX1a, PX1b, PX1c, PX1d) included in the first pixel group (PG1) toward the first floating diffusion region (FD1).

Photocharges corresponding to all first unit pixels (PX1a, PX1b, PX1c, PX1d) included in the first pixel group (PG1) may move to the first floating diffusion region (FD1), and may be output as a pixel signal (Vpixel_out) after passing through the first drive transistor (DX1) and the first selection transistor (SX1).

At this time, the output pixel signal may be a signal corresponding to incident light that has passed through the optical filter CF1 (see FIG. 2) included in the first pixel group (PG1). In other words, the pixel array 110 may output a signal corresponding to the intensity of incident light having a wavelength that has been selectively transmitted by the optical filter, as a pixel signal.

The processor 200 may calculate color data for each pixel (or pixel group) based on the output pixel signal, and may generate image data based on color data for each pixel or color data for each pixel group.

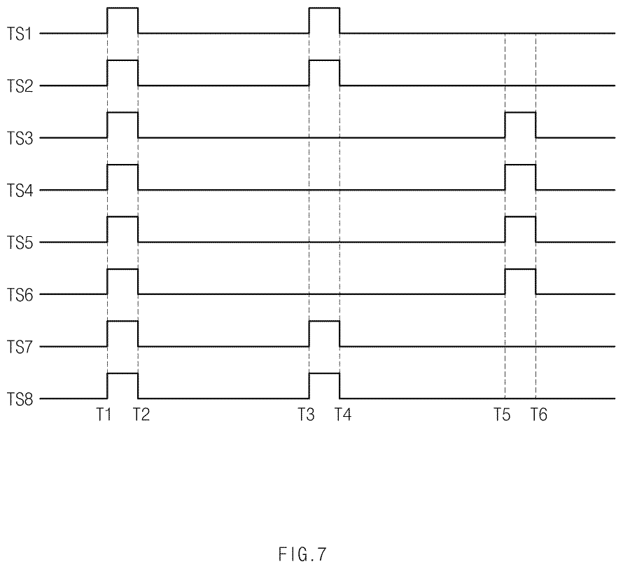

FIG. 7 is a timing diagram illustrating operations of transfer control signals provided to the pixel array shown in FIG. 2 according to embodiments of the disclosed technology.

The operation of the pixel array portion 110a shown in FIG. 2 will hereinafter be described with reference to FIGS. 2 and 7.

FIG. 7 shows activation time points of the first to eighth transfer control signals (TS1, TS2, TS3, TS4, TS5, TS6, TS7, TS8) provided to the pixel array portion 110a shown in FIG. 2 through the transfer control signal lines (TCL1, TCL2, TCL3, TCL4, TCL5, TCL6, TCL7, TCL8).

The first to eighth transfer control signals (TS1, TS2, TS3, TS4, TS5, TS6, TS7, TS8) may have an activation voltage level (e.g., logic high) during a time period from a first time point (T1) to a second time point (T2).

Each of the first time point T1 to the second time point T2 may be a reset time point. As the first reset control signal RS1 (see FIG. 6) has an activation level, the reset transistor (e.g., RX1 of FIG. 6) may perform a reset operation at each of the first time point T1 and the second time point T2.

After the reset operation, the first to eighth transfer control signals (TS1, TS2, TS3, TS4, TS5, TS6, TS7, TS8) may have a deactivation voltage level (e.g., logic low) until reaching a third time point (T3).

At this time, the unit pixels included in the pixel array 110 may receive incident light and may generate photocharges corresponding to the incident light in the photoelectric conversion region included in each unit pixel.

During a time period from the third time point (T3) to the fourth time point (T4), some transfer control signals may selectively have an activation voltage level (e.g., logic high).

Each of the third time point (T3) to the fourth time point (T4) may be an operation time point at which the phase signal is output.

For example, during a time period from the third time point (T3) to the fourth time point (T4), each of the first transfer control signal (TS1), the second transfer control signal (TS2), the seventh transfer control signal (TS7), and the eighth transfer control signal (TS8) may have an activation voltage level (e.g., logic high).

When some transfer control signals selectively have an activation voltage level, photocharges generated by unit pixels located at one side with respect to the center of the pixel group may move to the floating diffusion region included in the pixel group.

In some implementations, when the first transfer control signal (TS1), the second transfer control signal (TS2), the seventh transfer control signal (TS7), and the eighth transfer control signal (TS8) have an activation voltage level, photocharges generated by two first unit pixels (PX1a, PX1b) located upward with respect to the center of a pixel group (PG1) from among the first unit pixels (PX1a, PX1b, PX1c, PX1d) included in the first pixel group (PG1) may move to a first floating diffusion region included in a first pixel group (PG1), and photocharges generated by two second unit pixels (PX2a, PX2c) located to the left of the center of a second pixel group (PG2) from among second unit pixels (PX2a, PX2b, PX2c, PX2d) included in the second pixel group (PG2) may move to a second floating diffusion region included in the second pixel group (PG2).

In some implementations, photocharges generated by two third unit pixels (PX3c, PX3d) located downward with respect to the center of a third pixel group (PG3) from among the third unit pixels (PX3a, PX3b, PX3c, PX3d) included in the third pixel group (PG3) may move to a third floating diffusion region included in the third pixel group (PG3), and photocharges generated by two fourth unit pixels (PX4b, PX4d) located to the right of the center of a fourth pixel group (PG4) from among fourth unit pixels (PX4a, PX4b, PX4c, PX4d) included in the fourth pixel group (PG4) may move to a fourth floating diffusion region included in the fourth pixel group (PG4).

Accordingly, the respective pixel groups (PG1, PG2, PG3, PG4) may output phase signals corresponding to different phases as pixel signals.

The processor 200 can quickly generate phase data based on the phase signals without additional operations to obtain the phase signals.

After generating the phase data, the first to eighth transfer control signals (TS1, TS2, TS3, TS4, TS5, TS6, TS7, TS8) may have a deactivation voltage level (e.g., logic low) until reaching the fifth time point (T5).

Each of the third to sixth transfer control signals (TS3, TS4, TS5, TS6) may have an activation voltage level (e.g., logic high) during a time period from the fifth time point (T5) to the sixth time point (T6).

The time period from the fifth time point (T5) to the sixth time point (T6) may be an operation time in which phase signals opposite to the respective phase signals output from the time period from the third time point (T3) to the fourth time point (T4) are output.

When the third transfer control signal (TS3), the fourth transfer control signal (TS4), the fifth transfer control signal (TS5), and the sixth transfer control signal (TS6) have an activation voltage level, photocharges generated by two first unit pixels (PX1c, PX1d) located downward with respect to the center of the first pixel group (PG1) from among the first unit pixels (PX1a, PX1b, PX1c, PX1d) included in the first pixel group (PG1) may move to the first floating diffusion region included in the first pixel group (PG1), and photocharges generated by two second unit pixels (PX2b, PX2d) located to the right of the center of a second pixel group (PG2) from among the second unit pixels (PX2a, PX2b, PX2c, PX2d) included in the second pixel group (PG2) may move to the second floating diffusion region included in the second pixel group (PG2).

In addition, photocharges generated by two third unit pixels (PX3a, PX3b) located upward with respect to the center of the third pixel group (PG3) from among the third unit pixels (PX3a, PX3b, PX3c, PX3d) included in the third pixel group (PG3) may move to the third floating diffusion region included in the third pixel group (PG3), and photocharges generated by two fourth unit pixels (PX4a, PX4c) located to the left of the center of a fourth pixel group (PG4) from among the fourth unit pixels (PX4a, PX4b, PX4c, PX4d) included in the fourth pixel group (PG4) may move to the fourth floating diffusion region included in the fourth pixel group (PG4).

The interval from the fifth time point (T5) to the sixth time point (T6) may be substantially the same as the interval from the third time point (T3) to the fourth time point (T4). In other words, the time required to output one pair of phase signals corresponding to each other may be the same.

The image sensing device based on some implementations of the disclosed technology can obtain a total of four phase signal pairs through two phase signal output operations.

Additionally, the processor 200 may generate image data for each pixel group by summing one pair of phase signals corresponding to photocharges generated by each pixel group.

As is apparent from the above description, the image sensing device based on some implementations of the disclosed technology can generate image data and phase data based on pixel signals output from a pixel array.

The image sensing device based on some implementations of the disclosed technology can generate phase data based on pixel signals output from the pixel array, and can perform a phase-difference detection autofocus (PDAF) function using the generated phase data.

In addition, the image sensing device based on some implementations of the disclosed technology can simplify a readout operation by adjusting a layout structure of transfer control signal lines connected to unit pixels included in the pixel array.

The embodiments of the disclosed technology may provide a variety of effects capable of being directly or indirectly recognized through the above-mentioned patent document.

Those skilled in the art will appreciate that the disclosed technology may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a first pixel group formed to include a plurality of first unit pixels arranged in a row direction and a column direction, the first unit pixels configured to respond to incident light and generate first pixel signals, respectively;
a second pixel group disposed adjacent to the first pixel group in the row direction and including a plurality of second unit pixels arranged in the row direction and the column direction, the second unit pixels configured to respond to the incident light and generate second pixel signals, respectively;
a first transfer control signal line connected to any one of the first unit pixels located in a first direction with respect to a center of the first pixel group, and connected to any one of the second unit pixels located in a second direction perpendicular to the first direction with respect to a center of the second pixel group; and
a second transfer control signal line connected to a remaining one of the first unit pixels located in the first direction, and connected to a remaining one of the second unit pixels located in the second direction.

2. The image sensing device according to claim 1, further comprising:
a third transfer control signal line connected to any one of the first unit pixels located in a third direction opposite to the first direction, and connected to any one of the second unit pixels located in a fourth direction opposite to the second direction; and
a fourth transfer control signal line connected to a remaining one of the first unit pixels located in the third direction, and connected to a remaining one of the second unit pixels located in the fourth direction.

3. The image sensing device according to claim 2, further comprising:
a third pixel group disposed adjacent to the first pixel group in the column direction and including a plurality of third unit pixels, the third unit pixels configured to respond to incident light and generate third pixel signals, respectively;
a fourth pixel group disposed adjacent to the third pixel group in the row direction and including a plurality of fourth unit pixels, the fourth unit pixels configured to respond to incident light and generate fourth pixel signals, respectively; and
a fifth transfer control signal line, a sixth transfer control signal line, a seventh transfer control signal line, and an eighth transfer control signal line that are connected to the third unit pixels and the fourth unit pixels.

4. The image sensing device according to claim 3, further comprising:
a processor configured to calculate image data based on pixel signals that are output from the first pixel group, the second pixel group, the third pixel group, and the fourth pixel group, in response to transfer control signals having an activation voltage level, the transfer control signals provided through the first transfer control signal line, the second transfer control signal line, the third transfer control signal line, the fourth transfer control signal line, the fifth transfer control signal line, the sixth transfer control signal line, the seventh transfer control signal line, and the eighth transfer control signal line.

5. The image sensing device according to claim 3, wherein:
the fifth transfer control signal line is connected to any one of the third unit pixels located in the first direction with respect to the center of the third pixel group, and is connected to any one of the fourth unit pixels located in the second direction with respect to the center of the fourth pixel group, and
the sixth transfer control signal line is connected to a remaining one of the third unit pixels located in the first direction and is connected to a remaining one of the fourth unit pixels located in the second direction.

6. The image sensing device according to claim 5, further comprising:
a processor configured to calculate phase data based on pixel signals that are output from the first pixel group, the second pixel group, the third pixel group, and the fourth pixel group, in response to transfer control signals having an activation voltage level, the transfer control signals provided through the first transfer control signal line, the second transfer control signal line, the seventh transfer control signal line, and the eighth transfer control signal line.

7. The image sensing device according to claim 3, wherein:
the fifth transfer control signal line is connected to any one of the third unit pixels located in the second direction with respect to the center of the third pixel group, and is connected to any one of the fourth unit pixels located in the first direction with respect to the center of the fourth pixel group, and
the sixth transfer control signal line is connected to a remaining one of the third unit pixels located in the second direction, and is connected to a remaining one of the fourth unit pixels located in the first direction.

8. The image sensing device according to claim 7, further comprising:
a processor configured to calculate phase data based on pixel signals that are output from the first pixel group, the second pixel group, the third pixel group, and the fourth pixel group, in response to transfer control signals having an activation voltage level, the transfer control signals provided through the first transfer control signal line, the second transfer control signal line, the seventh transfer control signal line, and the eighth transfer control signal line.

9. The image sensing device according to claim 3, wherein:
the fifth transfer control signal line is connected to any one of the third unit pixels located in the third direction with respect to the center of the third pixel group, and is connected to any one of the fourth unit pixels located in the fourth direction with respect to the center of the fourth pixel group, and
the sixth transfer control signal line is connected to a remaining one of the third unit pixels located in the third direction and is connected to a remaining one of the fourth unit pixels located in the fourth direction.

10. The image sensing device according to claim 9, further comprising:
a processor configured to calculate phase data based on pixel signals that are output from the first pixel group, the second pixel group, the third pixel group, and the fourth pixel group, in response to transfer control signals having an activation voltage level, the transfer control signals provided through the first transfer control signal line, the second transfer control signal line, the fifth transfer control signal line, and the sixth transfer control signal line.

11. The image sensing device according to claim 3, wherein:
the fifth transfer control signal line is connected to any one of the third unit pixels located in the fourth direction with respect to the center of the third pixel group, and is connected to any one of the fourth unit pixels located in the third direction with respect to the center of the fourth pixel group, and
the sixth transfer control signal line is connected to a remaining one of the third unit pixels located in the fourth direction and is connected to a remaining one of the fourth unit pixels located in the third direction.

12. The image sensing device according to claim 11, further comprising:
a processor configured to calculate phase data based on pixel signals that are output from the first pixel group, the second pixel group, the third pixel group, and the fourth pixel group, in response to transfer control signals having an activation voltage level, the transfer control signals provided through the first transfer control signal line, the second transfer control signal line, the fifth transfer control signal line, and the sixth transfer control signal line.

13. The image sensing device according to claim 1, further comprising:
a row driver configured to provide a transfer control signal having an activation voltage level or a deactivation voltage level through each transfer control signal line.

14. The image sensing device according to claim 1, further comprising:
a first microlens disposed to overlap the first pixel group; and
a second microlens disposed to overlap the second pixel group.

15. The image sensing device according to claim 1, wherein:
each of the first unit pixels includes a first optical filter, and
each of the second unit pixels includes a second optical filter.

16. The image sensing device according to claim 15, further comprising:
a third pixel group disposed adjacent to the first pixel group in the column direction and including a plurality of third unit pixels; and
a fourth pixel group disposed adjacent to the third pixel group in the row direction and including a plurality of fourth unit pixels,
wherein
each of the third unit pixels includes a third optical filter, and
each of the fourth unit pixels includes the first optical filter.

17. An image sensing device comprising:
a first pixel group including a plurality of first transfer transistors arranged in two rows and two columns; and
a second pixel group including a plurality of second transfer transistors arranged in another two rows and another two columns and disposed adjacent to the first pixel group in a row direction,
wherein
two second transfer transistors located in a second direction with respect to a center of the second pixel group are simultaneously activated in response to an activation of two first transfer transistors located in a first direction with respect to a center of the first pixel group, the first direction being perpendicular to the second direction.

18. The image sensing device according to claim 17, further comprising:
a first microlens disposed to overlap the first pixel group; and
a second microlens disposed to overlap the second pixel group.

19. The image sensing device according to claim 17, further comprising:
a third pixel group including a plurality of third transfer transistors and disposed adjacent to the first pixel group in a column direction; and
a fourth pixel group including a plurality of fourth transfer transistors and disposed to be in contact the third pixel group in the row direction, wherein
in response to an activation of two first transfer transistors located in the first direction, two third transfer transistors located in a third direction opposite to the first direction are activated simultaneously, and two fourth transfer transistors located in a fourth direction opposite to the second direction are activated simultaneously.

20. The image sensing device according to claim 17, further comprising:
a third pixel group including a plurality of third transfer transistors and disposed to be in contact with the first pixel group in a column direction; and
a fourth pixel group including a plurality of fourth transfer transistors and disposed to be in contact with the third pixel group in the row direction,
wherein
in response to an activation of two first transfer transistors located in the first direction, two third transfer transistors located in a fourth direction opposite to the second direction are activated simultaneously, and two fourth transfer transistors located in a third direction opposite to the first direction are activated simultaneously.
